(19) United States
(12) Patent Application Publication
(10) Pub. No.: US 2026/0334136 A1
(43) Pub. Date: Oct. 22, 2026

(54) BOAT LOADING DEVICE AND WAFER PROCESSING SYSTEM COMPRISING SAME

(71) Applicant: HANWHA SOLUTIONS CORPORATION, Seoul (KR)

(72) Inventors: Jong Kuk HAN, Seoul (KR); Young Gi KIM, Seoul (KR); Min Ho Kim, Seoul (KR); Hyun Ho LEE, Seoul (KR); Sang Tae PARK, Seoul (KR)

(73) Assignee: HANWHA SOLUTIONS CORPORATION, Seoul (KR)

(21) Appl. No.: 19/122,482

(22) PCT Filed: Aug. 18, 2023
(86) PCT No.: PCT/KR2023/012254

§ 371 Date: Apr. 18, 2025

(30) Foreign Application Priority Data
Oct. 18, 2022 (KR) 10-2022-0134455

(51) Int. Cl. H10P 72/00; H10P 72/10; H10P 72/30

(52) U.S. Cl. CPC H10P 72/0436; H10P 72/13; H10P 72/3304; H10P 72/3402; H10P 72/3411

(57) ABSTRACT

A boat loading device is a device that loads a boat stacked with a plurality of wafers before introduction into a process chamber, and comprises: a pair of paddles that support and transport the boat; and a heater, adjacent to the pair of paddles, that heats the boat at a bottom surface of the boat, wherein, after the heater heats the boat to a predetermined temperature, the boat may be introduced into the process chamber.

### TECHNICAL FIELD

The present disclosure relates to a boat loading device and a wafer processing system.

### BACKGROUND ART

Wafers are supported on a boat, stored, and transferred, and then moved to a process chamber to be processed. In general, a zone in which boats are stored and transferred has a temperature close to room temperature, but a process chamber is maintained at a temperature of several hundred degrees or more to heat-treat wafers. Therefore, it takes a lot of time to heat boats and wafers, which are at room temperature, in a process chamber, and a temperature difference occurs according to positions of the boat and the wafer. Thus, since a waiting time is increased to eliminate a temperature gradient between a boat and a wafer, and an overall heat treatment time is increased, manufacturing efficiency is degraded.

As a related art for solving such problems, there is a technology for preheating a boat using a preheating device before the boat is inserted into a process chamber. For example, conventional preheating devices have a cylindrical shape to surround a boat positioned therein and heats the boat using heating wires positioned along an inner wall.

However, such types of preheating devices rely on radiant heat to heat a boat, which results in a non-uniform temperature distribution due to a difference in distance between a center of the boat and a portion, at which a heating wire is positioned, and the outside.

### DISCLOSURE

### Technical Problem

A boat loading device and a wafer handling system including the same provide a boat loading device capable of preheating a boat, and a wafer handling system capable of preheating a boat in a loading process as well as boat loading and boat transferring processes.

### Technical Solution

A boat loading device, which is a device for loading a boat stacked with a plurality of wafers before the boat is inserted into a process chamber, includes a pair of paddles configured to support and transfer the boat, and a heater which is adjacent to the pair of paddles and heats the boat on a bottom surface of the boat, wherein the boat may be inserted into the process chamber after the heater heats the boat to a predetermined temperature.

The pair of paddles may be spaced apart from each other on the bottom surface of the boat, and the heater may be positioned between the pair of paddles and may overlap a center of the boat in a width direction.

The heater may be positioned at least along an entire longitudinal direction of the plurality of wafers, which are stacked in the boat.

The boat loading device may further include a shielding plate positioned between the pair of paddles and configured to surround the heater.

The heater may include a lamp configured to radiate light, and an inner surface of the shield plate facing the heater may be made of a material capable of reflecting the light.

The shielding plate may have two ends in a width direction adjacent to the pair of paddles and may be formed to be inclined such that a cross-sectional area thereof gradually decreases downward.

A wafer processing system includes a process chamber configured to heat boats each stacked with a plurality of wafers in a predetermined atmosphere, a boat stacking device configured to stack the plurality of boats, a boat transfer device configured to transfer the boats, and a boat loading device configured to load the boats transferred from the boat transfer device and insert the boats into the process chamber, wherein at least one of the boat stacking device, the boat transfer device, and the boat loading device may preheat the boat before the boat is inserted into the process chamber.

The at least one of the boat stacking device, the boat transfer device, and the boat loading device may include a heater which overlaps a center of the boat on a bottom surface of the boat and heats the boat.

The at least one of the boat stacking device, the boat transfer device, and the boat loading device may further include a shielding plate configured to surround the heater.

### ADVANTAGEOUS EFFECTS

A wafer processing system can preheat a boat before the boat is inserted into a processor chamber, reducing a time required to heat the boat in the process chamber. In addition, a temperature difference between an outer side and a center of the boat can be reduced, which can improve wafer quality.

A boat loading device, a boat stacking device, and a boat transfer device can effectively heat a center of a boat using a heater and a shielding plate.

### DESCRIPTION OF DRAWINGS

FIG. 1 schematically illustrates a wafer processing system.

FIGS. 2 and 3 illustrate a boat loading device.

FIGS. 4 and 5 are an enlarged front view of the boat loading device.

FIG. 6 is a cross-sectional view of the boat loading device.

FIG. 7 is a bottom view of the boat loading device.

FIG. 8 illustrates a boat stacking device.

FIG. 9 is a cross-sectional view of the boat stacking device.

FIG. 10 illustrates a boat transfer device.

FIG. 11 is a cross-sectional view of the boat transfer device.

### BEST MODE

A boat loading device, which is a device for loading a boat loaded with a plurality of wafers before the boat is inserted into a process chamber, includes a pair of paddles configured to support and transfer the boat, and a heater which is adjacent to the pair of paddles and heats the boat on a bottom surface of the boat, wherein the boat may be inserted into the process chamber after the heater heats the boat to a predetermined temperature.

### MODES OF THE INVENTION

Hereinafter, the present disclosure will be described with reference to embodiments shown in the accompanying drawings. Embodiments to be described are not limited to the contents to be described in the present specification and may have different forms. Therefore, the embodiments are described below only with reference to the drawings to describe aspects and features of the present disclosure.

The present disclosure includes various embodiments and modifications, and specific embodiments of which are illustrated in the drawings and described below. However, the present disclosure is not limited to the above-described embodiments, and includes all modifications, equivalents, and substitutes included in the spirit and scope of the present disclosure.

When an element or layer is referred to as being “on,” “connected to,” or “coupled to” another element or layer, the element or layer may be directly on, connected to, or coupled to another element or layer. Alternatively, one or more additional elements or layers may be additionally present. When an element is referred to as being “directly on,” “directly connected to,” or “directly coupled to” another element or layer, there may not be any other intermediate elements or layers present. For example, when a first element is described as being “coupled to” or “connected to” a second element, the first element may be directly coupled or connected to the second element, or the first element may be indirectly coupled or connected to the second element through one or more intermediate elements.

Dimensions of various elements, layers, or the like in the drawings may be exaggerated for clarity of illustration. Like reference numerals refer to like elements. As used herein, the term “and/or” includes any and all combinations of one or more of the associated listed items. In addition, the use of “may” when describing embodiments of the present disclosure relates to “one or more embodiments of the present disclosure.” Expression such as “at least one of” when preceding a list of elements may modify the entire list of elements and may not modify the individual elements of the list. For example, the expression “at least one of a, b, or c” may represent only a, only b, only c, both a and b, both a and c, both b and c, all a, b, and c, or variations thereof. As used herein, the terms “use,” “using,” and “used” may be considered synonymous with the terms “utilize,” “utilizing,” and “utilized,” respectively. As used herein, the term “substantially,” “about,” and similar terms are used as terms of approximation and not as terms of degree, and are intended to account for the inherent deviations in measured or calculated values that would be recognized by those of ordinary skill in the art.

Although the terms first, second, third, and the like may be used herein to describe various elements, components, regions, layers, and/or sections, these elements, components, regions, layers, and/or sections are not limited to these terms. These terms are used to distinguish one element, component, area, layer, or cross-section from another element, component, area, layer, or cross-section. Accordingly, a first element, a first component, a first region, a first layer, or a first cross section to be described below may be termed a second element, a second component, a second region, a second layer, or a second cross section without departing from the disclosure of the embodiments.

Spatially relative terms such as “below,” “lower,” “on,” “upper,” and the like may be used herein for convenience of description to describe the relationship of one element or feature to other element(s) or to feature(s) shown in the drawings. Spatially relative terms may include other directions of a device in use or operation in addition to the directions shown in the drawings. For example, when the device in the drawings is turned over, elements described as “below” or “beneath” other elements or features would then be disposed “above” or “over” the other elements or features. Thus, the term “below” may include both orientations of above and below. The device may be otherwise oriented (rotated 90 degrees or at other orientations), and the spatially relative descriptors used herein interpreted accordingly.

The terms used in this specification are merely used to describe embodiments of the present disclosure and are not intended to limit the present disclosure. As used herein, the singular form may also include the plural form unless the context clearly indicates otherwise. The terms “comprises,” “comprising,” “includes,” and the like specify the presence of stated features, integers, steps, operations, elements, and/or components but do not preclude the presence or addition of one or more other functions, integers, steps, operations, elements, components, and/or groups thereof.

When embodiments may be implemented with a processor, the specific process order may be performed differently from the described order. For example, two consecutively described processes may be performed substantially at the same time or may be performed in an order opposite to the described order.

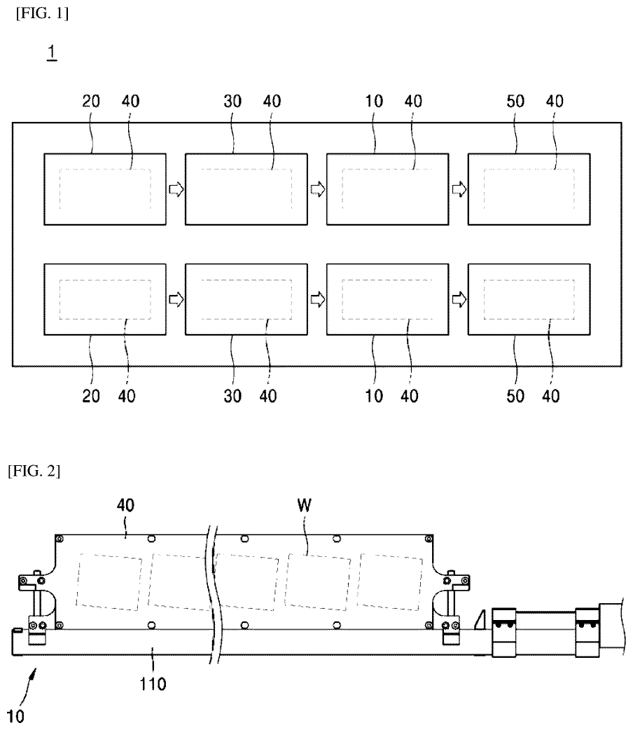

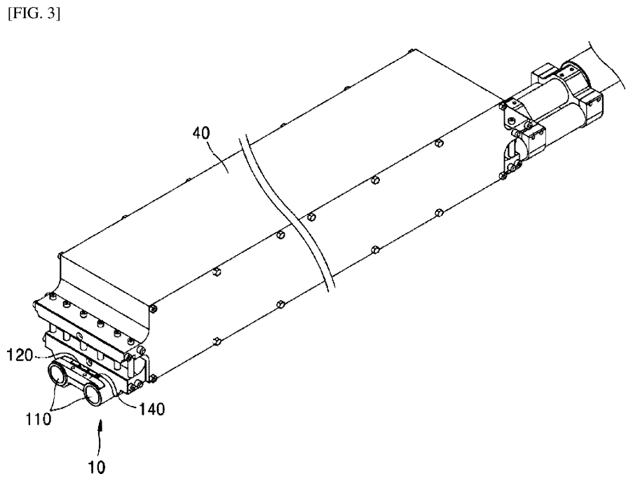

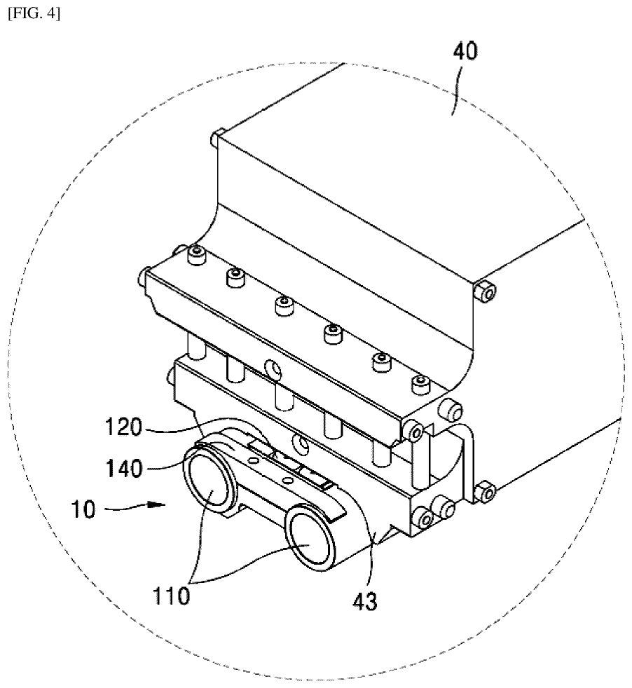

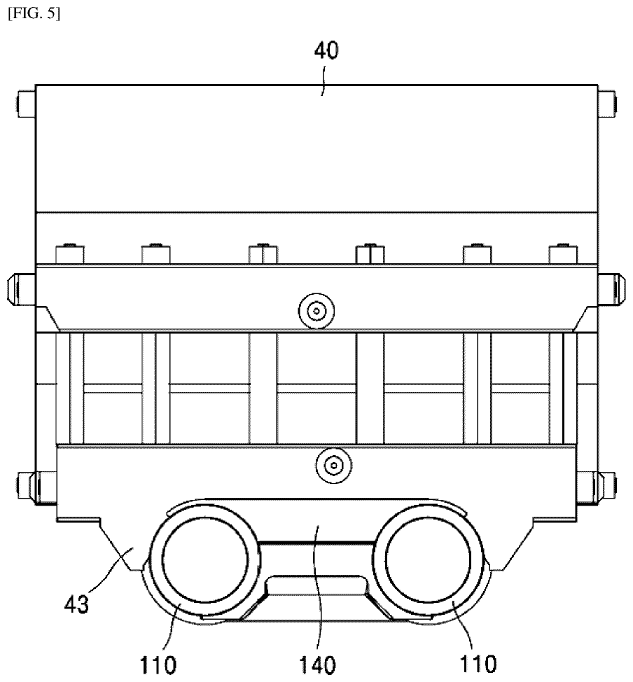

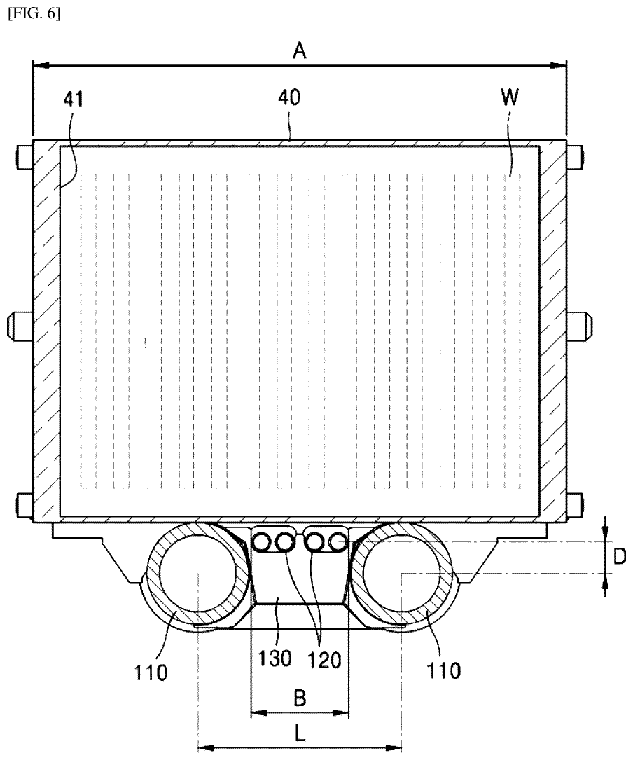

FIG. 1 schematically illustrates a wafer processing system 1. FIGS. 2 and 3 illustrate a boat loading device 10. FIGS. 4 and 5 are enlarged front views of the boat loading device 10. FIG. 6 is a cross-sectional view of the boat loading device 10. FIG. 7 is a bottom view of the boat loading device 10. For example, FIG. 7 illustrates a bottom surface of the boat loading device 10 from which a shielding plate 130 is removed.

The wafer processing system 1 may include a series of processes of processing a wafer W and a device for processing the same. For example, the wafer processing system 1 may be a system in which a deposition process is used to form a thin film on the wafer W. Alternatively, the wafer processing system 1 may be another apparatus used in a semiconductor manufacturing process. The wafer processing system 1 may include a boat 40, a boat stacking device 20, a boat transfer device 30, the boat loading device 10, and a process chamber 50.

The boat 40 is a device for stacking and transporting the wafer W. For example, as shown in FIG. 2, while stacking a plurality of wafers W therein, as shown in FIG. 1, the boat 40 may sequentially move through the boat stacking device 20, the boat transfer device 30, the boat loading device 10, and the process chamber 50. The plurality of wafers W may be stacked in the boat 40. For example, the plurality of wafers W may be arranged in one direction (for example, a longitudinal direction of the boat 40) and another direction intersecting the one direction (for example, a width direction of the boat 40). The number of wafers W is not limited, and 10 or more or 100 or more wafers W may be stacked in one boat 40.

The boat 40 may be positioned in a waiting space while stacked in the boat stacking device 20. Thereafter, the boat transfer device 30 transfers the boat 40 from the boat stacking device 20 to the boat loading device 10. The boat 40 waits in the boat loading device 10 and then enters the process chamber 50.

The boat 40 may include a body 41 and a guide 43. As shown in FIG. 6, the body 41 has an interior space in which the wafer W is stacked. The plurality of wafers W may be spaced apart from each other while standing up inside the body 41. The guide 43 may be disposed on a bottom surface of the body 41 and may have a wedge shape protruding downward. The guide 43 may be positioned on the bottom surface of the body 41, and a paddle 110 may be positioned adjacent to the guide 110. For example, the guide 43 may include two guides 43, and two paddles 110 may be supported between the two guides 43.

When the boat 40 is inserted into the process chamber 50, the process chamber 50 may perform a wafer processing process by heating the boat 40 in a predetermined atmosphere. For example, the process chamber 50 may heat the boat 40 using a heater such as a heating wire surrounding the boat 40. For example, the process chamber 50 may be a deposition device. The process chamber 50 may receive a deposition gas to heat-treat the wafer W to form a thin film on the wafer W. Alternatively, the process chamber 50 may be another device used in a semiconductor manufacturing process.

The boat loading device 10 may include the paddle 110 and a heater 120.

The paddle 110 is positioned below the boat loading device 10 and supports and transports the boat 40. For example, as shown in FIG. 2, the paddle 110 may extend in one direction (for example, a longitudinal direction of the boat loading device 10), and the boat 40 may be seated thereon. The paddle 110 may move while supporting the boat 40 to move the boat 40 into the process chamber 50. Alternatively, while the paddle 110 supports the boat 40, a separate pusher, a slider, or the like may be used to push and move the boat 40 to the process chamber 50.

The paddle 110 may consist of a pair of tubes. For example, as shown in FIG. 3, the paddle 110 may extend in one direction (for example, the longitudinal direction of the boat 40), and a pair of paddles 110 may be spaced apart from each other in a width direction. In addition, as shown in FIG. 6, centers of the pair of paddles 110 may be spaced apart from each other by an interval L, and the heater 120 to be described below may be positioned in the interval L.

A distance B between two ends of the heater 120 may satisfy 20% to 50% of a width A of the boat 40. When B/A is less than 20%, a width of the heater 120 may be too small to sufficiently heat the boat 40. In addition, when B/A exceeds 50%, the width of the heater 120 excessively increases to increase the interval between the paddles 110, which causes the overall size of the boat loading device 10 to be excessively increased.

The heater 120 heats the boat 40 at one side of the boat loading device 10. The heater 120 may heat the boat 40 to a predetermined temperature before the boat 40 is inserted into the process chamber 50, thereby reducing a time required to heat the boat 40 in the process chamber 50 to short a time of the overall process.

The heater 120 may be positioned below the boat 40. As shown in FIGS. 3 and 4, the boat 40 may be heated below the boat 40. In addition, the heater 120 may be longer than the boat 40 and may be positioned in one direction (for example, the longitudinal direction of the boat 40). Alternatively, the heater 120 may have a length sufficient to cover all of the plurality of wafers W in the boat 40.

In this way, the heater 120 may rapidly increase a temperature of a center of the boat 40 by heating the boat 40 below the boat 40. Thus, a temperature difference between an outer side and the center of the boat 40 may be reduced as compared to a method of heating the boat outside the boat 40.

A method in which the heater 120 heats the boat 40 is not particularly limited. For example, the heater 120 may include a heating wire, and when a current is applied, the heating wire may be heated to a predetermined temperature to heat the boat 40.

In one embodiment, the heater 120 may be positioned between the paddles 110. As shown in FIG. 6, the heater 120 may be positioned between the pair of paddles 110 and may be in contact with the bottom surface of the boat 40. Accordingly, a heating area is partitioned by the pair of paddles 110 and the boat 40, and the heater 120 positioned in the heating area may intensively heat the bottom surface of the boat 40.

The heater 120 may be spaced apart from the paddle 110 in a height direction. For example, as shown in FIG. 6, a center of the heater 120 may be spaced apart from the center of the paddle 110 by an interval D.

The interval D may be 55% or more, preferably, 60% to 90%, of a distance from a lower surface of the body 41 to the center of the paddle 110. When a corresponding ratio is less than 60%, the paddles 110 are more widely spaced apart from each other as a size of the heater 120 increases, and thus the size of the boat loading device 10 may be increased. In addition, when the ratio exceeds 90%, the size of the heater 120 is excessively decreased, which reduces heating efficiency, and a distance between the shielding plate 130 and the heater 120 is increased, which makes it impossible for the shielding plate 130 to efficiently shield or reflect heat generated by the heater 120.

The heater 120 may include a plurality of heating wires. For example, as shown in FIGS. 6 and 7, the heating wire of the heater 120 may be positioned on the bottom surface of the boat 40 and may have a U-shape. The heating wire of the heater 120 extending from one end of the boat 40 may be bent in a opposite direction at the other end of the boat 40 to extend again to the other end of the boat 40.

In another embodiment, the heater 120 may have a shape that is repeatedly bent in another direction (for example, the width direction of the boat 40). That is, the heater 120 may be repeatedly bent in a U shape in the width direction of the boat 40 while extending in one direction (for example, the longitudinal direction of the boat 40) between the pair of paddles 110.

The heater 120 may overlap the center of the boat 40 in the width direction. Thus, the center of the boat 40 may be heated to a target temperature more quickly, thereby making a temperature gradient between the center and the outer side of the boat 40 more uniform in the process chamber 50.

The boat loading device 10 may further include the shielding plate 130. The shielding plate 130 can prevent heat emitted from the heater 120 from being dissipated to the outside of the boat loading device 10, thereby increasing the heating efficiency of the heater 120.

As shown in FIG. 6, the shielding plate 130 may be positioned between the pair of paddles 110 and may surround the heater 120. The shielding plate 130 may have two ends adjacent to the pair of paddles 110 in a width direction and may extend inward therefrom to form an interior space. The heater 120 may be disposed in the interior space of the shielding plate 130. The shielding plate 130 may be positioned at the entirety of the heater 120 in a longitudinal direction.

After the heater 120 heats the boat 40 to a predetermined temperature, the boat loading device 10 may insert the boat 40 into the process chamber 50.

Due to the configuration described above, the boat loading device 10 may limit a heating area of the heater 120 to the bottom surface of the boat 40, an area between the pair of paddles 110, and the inside of the shielding plate 130. Accordingly, heat generated by the heater 120 can be prevented from being dissipated to the outside of the boat loading device 10, for example, to the bottom of the boat loading device 10. In addition, the shielding plate 130 may be made of a material having lower thermal conductivity than other components of the boat loading device 10.

For insulation, the interior space of the shielding plate 130 may have a rarefied atmosphere as compared to the outside of the boat loading device 10.

A bottom surface of the shielding plate 130 may be positioned at a higher level than a bottom surface of the pair of paddles 110 and may also be positioned at a lower level of the center of the paddles 110. Thus, interference with the shielding plate 130 can be reduced when the paddle 110 moves the boat 40. In addition, an appropriate gap may be formed between the heater 120 and the shielding plate 130 to prevent the shielding plate 130 from being excessively heated and deformed.

The shielding plate 130 may have a shape that extends to be inclined inward in a downward direction. As shown in FIG. 6, the shielding plate 130 may have a shape in which a cross-sectional area gradually decreases downward. Thus, heating efficiency can be increased by reducing the interior space of the shielding plate 130, that is, heat capacity.

The heater 120 may further include a lamp that generates heat by radiating light with a specific wavelength, and an inner surface of the shielding plate 130 facing the heater 120 may have made of a material capable of reflecting light radiated by the heater 120. Thus, light radiated by the heater 120 may be reflected by the shielding plate 130 and concentrated on the bottom surface of the boat 40.

The boat loading device 10 may include a clamp 140. As shown in FIG. 3, the clamp 140 may be positioned at one side of the pair of paddles 110 and may support the pair of paddles 110. One clamp 140 may be positioned at each of one end portion and the other end portion of the pair of paddles 110 in a longitudinal direction, or a plurality of clamps 140 may be positioned therebetween.

The clamp 140 may be positioned at each of two end portions of the heater 120 in a longitudinal direction. Thus, heat generated by the heater 120 may remain between the paddle 110, the boat 40, the shielding plate 130, and the clamp 140, thereby increasing the heating efficiency of the heater 120.

Due to the configuration described above, the boat loading device 10 may preheat the boat 40 to a predetermined temperature before the boat 40 is inserted into the process chamber 50. Accordingly, a time required to heat the boat 40 in the process chamber 50 can be reduced. In addition, by heating a center of the bottom surface of the boat 40 through the heater 120, a temperature gradient between the outer side and the center of the boat 40 can be made uniform during a heating process in the process chamber 50.

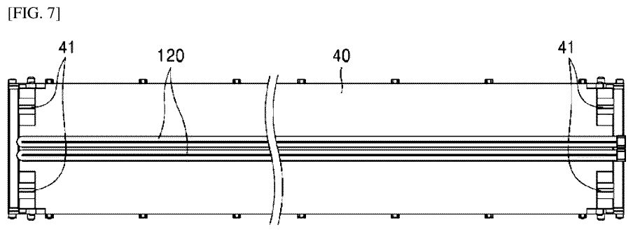

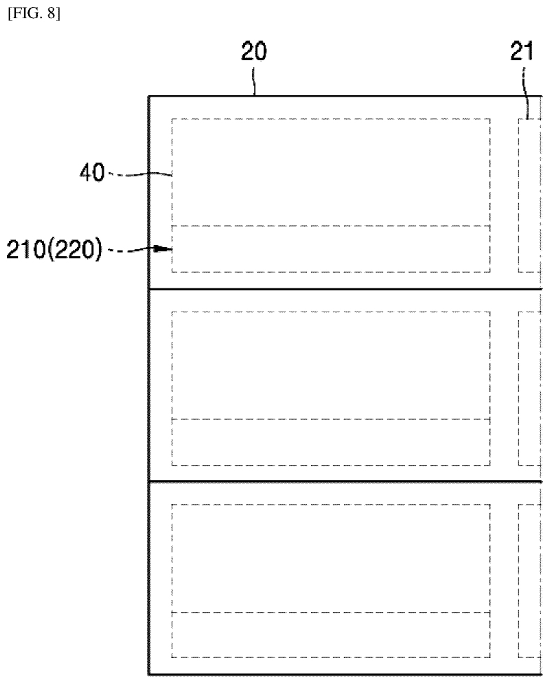

FIG. 8 illustrates the boat stacking device 20. FIG. 9 is a cross-sectional view of the boat stacking device 20.

The boat stacking device 20 stacks and stores the boat 40 introduced from outside in a designated zone. For example, as shown in FIG. 8, the boat stacking device 20 may store a plurality of boats 40 to be separated from each other therein. The shape, size, type, or the like of the boat stacking device 20 are not particularly limited, and for example, the boat stacking device 20 may have a closed shelf shape consisting of a plurality of stages.

The boat stacking device 20 may include a door 21. As shown in FIG. 8, the boat 40 stacked in the boat stacking device 20 may be towed or may enter the boat loading device 20 through the door 21 positioned at one side of the boat stacking device 20.

The boat stacking device 20 may include a heater 210 and a shielding plate 220. As shown in FIGS. 8 and 9, the heater 210 may be positioned inside the boat stacking device 20 together with the boat 40. For example, the heater 210 may be provided for each of the plurality of boats 40 stacked in the boat stacking device 20. The heater 210 may be in contact with the bottom surface of the boat 40 to heat the boat 40. Thus, the boat 40 may be preheated from the boat stacking device 20, thereby reducing a time required to heat the boat 40 in the process chamber 50.

The heater 210 may consist of a plurality of heating wires. In addition, the heater 210 may overlap the center of the boat 40 in the width direction to intensively heat the center of the boat 40. The heater 210 may cover the entirety of the boat 40 in the longitudinal direction. Alternatively, the heater 210 may cover all of the plurality of wafers W, which are stacked inside the boat 40, in a longitudinal direction.

Alternatively, the heater 210 may cover the entirety of the boat 40 in the width direction. That is, although the heater 210 is illustrated in FIG. 9 as including four heating wires and overlapping a portion of the boat 40, the present disclosure is not limited thereto. The plurality of heating wires provided in the heater 210 cover the entirety of the boat 40 in the width direction to heat the entire bottom surface of the boat 40 more stably, thereby alleviating a temperature gradient according to a position of the boat 40.

The shielding plate 220 may surround the heater 210 and may prevent heat by the heater 210 from being dissipated to the outside. For example, as shown in FIG. 9, the shielding plate 220 may be positioned on the bottom surface of the boat 40 such that the heater 210 is positioned therein and may prevent heat generated by the heater 210 from being dissipated to the outside.

A configuration of the heater 210 and the shielding plate 220 may be the same as that of the heater 120 and the shielding plate 130 of the boat loading device 10 described above, and a detailed description thereof is omitted. For example, the heater 210 may be a lamp that radiates light, and the shielding plate 220 may have a inclined shape such that a cross-sectional area gradually decreases downward. In addition, the shielding plate 220 may have an inner surface made of a material capable of reflecting light.

The heater 210 and the shielding plate 220 may be attached to or detached from the boat 40. For example, the heater 210 and shielding plate 220 may positioned in a housing and may be moved relative to the boat 40 through separate rollers or sliders. In addition, the heater 210 and the shielding plate 220 may be in a state in which the boat stacking device 20 is fixed.

The boat stacking device 20 notifies the wafer processing system 1 of this when the heater 210 heats the boat 40 to a predetermined temperature, and the wafer processing system 1 may take the boat 40 out of the boat stacking device 20 using the boat transfer device 30.

Through such a configuration, the boat stacking device 20 may preheat the boat 40 to a predetermined temperature while the boat 40 is stacked, thereby reducing a time required for heating in the process chamber 50.

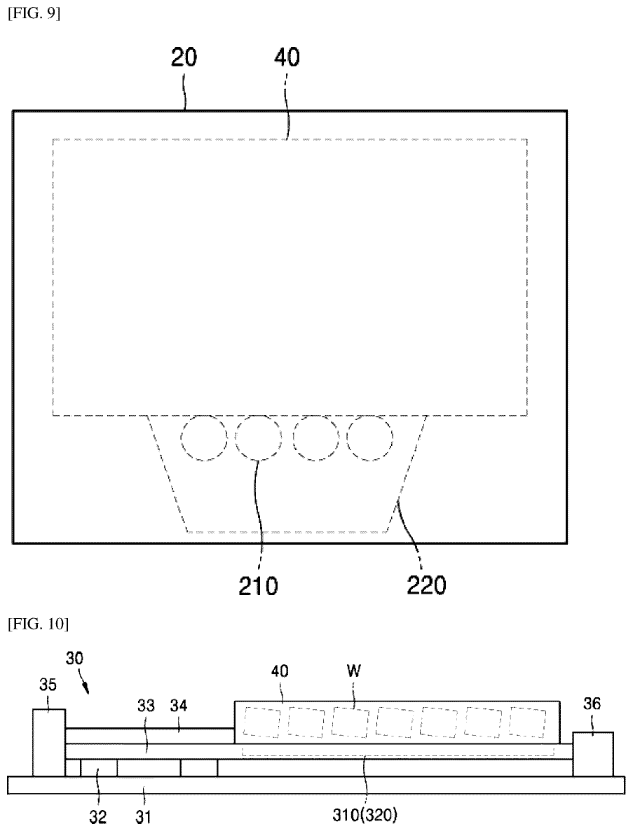

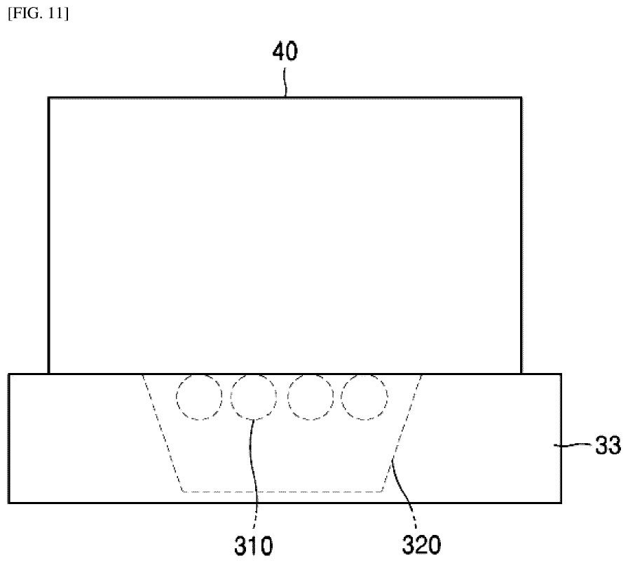

FIG. 10 illustrates the boat transfer device 30, and FIG. 11 is a cross-sectional view of the boat transfer device 30.

The boat transfer device 30 takes the boat 40 out of the boat stacking device 20 and transfers the boat 40 to the boat loading device 10.

The boat transfer device 30 may include a main frame 31 that is elongated in a longitudinal direction and supports other components of the boat transfer device 30 and a plurality of subframes 32 disposed on the main frame 31. A support plate 33 that supports the boat 40 may be positioned on the subframe 32, a manipulation part 35 may be positioned at one end portion of the support plate 33, and a fixing part 36 may be positioned at the other end portion of the support plate 33. In addition, a pusher 34 may be disposed at one side of the manipulation part 35, and by the operation of the manipulation part 35, the pusher 34 may slide or roll on the support plate 33 to press and move the boat 40.

The boat transfer device 30 may include a heater 310 and a shielding plate 320. As shown in FIG. 10 and FIG. 11, the heater 310 and the shielding plate 320 may be positioned inside the support plate 33 to heat the boat 40.

The heater 310 may be positioned inside the support plate 33 in a longitudinal direction and may have a length that is greater than or equal to that of the boat 40. Alternatively, the heater 310 may have a length that is at least greater than the total length of the plurality of wafers W stacked in the boat 40. In another embodiment, the heater 310 may be positioned in the entirety of the support plate 33. The heater 310 may preheat the boat 40 during a process in which the boat transfer device 30 transfers the boat 40, thereby reducing a time required to heat the boat 40 in the process chamber 50.

The heater 310 may consist of a plurality of heating wires. In addition, the heater 310 may overlap the center of the boat 40 in the width direction to intensively heat the center of the boat 40. The heater 310 may cover the entirety of the boat 40 in the longitudinal direction. Alternatively, the heater 310 may cover all of the plurality of wafers W, which are stacked inside the boat 40, in the longitudinal direction.

Alternatively, the heater 310 may cover the entirety of the boat 40 in the width direction. That is, although the heater 310 is illustrated in FIG. 11 as including four heating wires and overlapping a portion of the boat 40, the present disclosure is not limited thereto. The plurality of heating wires provided in the heater 310 cover the entirety of the boat 40 in the width direction to heat the entire bottom surface of the boat 40 more stably, thereby alleviating a temperature gradient according to a position of the boat 40.

The shielding plate 320 may surround the heater 310 and may prevent heat by the heater 310 from being dissipated to the outside. For example, as shown in FIG. 11, the shielding plate 320 may be positioned on the bottom surface of the boat 40 such that the heater 310 is positioned therein and may prevent heat generated by the heater 310 from being dissipated to the outside.

A configuration of the heater 310 and the shielding plate 320 may be the same as that of the heater 120 and the shielding plate 130 of the boat loading device 10 described above, and a detailed description thereof is omitted. For example, the heater 310 may be a lamp that radiates light, and the shielding plate 320 may have a inclined shape such that a cross-sectional area gradually decreases downward. In addition, the shielding plate 320 may have an inner surface made of a material capable of reflecting light.

After the heater 310 heats the boat 40 to a predetermined temperature, the boat transfer device 30 may transfer the boat 40 to the boat loading device 10.

Due to the configuration described above, the boat transfer device 30 may preheat the boat 40 to a predetermined temperature while the boat 40 is stacked, thereby reducing a time required for heating in the process chamber 50.

The wafer processing system 1 may preheat the boat 40 before at least one of the boat stacking device 20, the boat transfer device 30, and the boat loading device 10 inserts the boat 40 into the process chamber 50. Thus, a time taken for the process chamber 50 to heat the boat 40 can be reduced, and a temperature gradient between the outer side and the center of the boat 40 can be alleviated.

As described above, the present disclosure has been described with reference to the embodiment shown in the drawings, but this is only an example. Those of ordinary skill in the art may fully understand that various modifications and equivalent other embodiments are possible from the embodiments. Therefore, the true technical protection scope of the present disclosure should be determined based on the appended claims.

### INDUSTRIAL APPLICABILITY

The present disclosure can be used in the industry of a boat loading device and a wafer processing apparatus including the same.

1. A boat loading device, which is a device for loading a boat stacked with a plurality of wafers before the boat is inserted into a process chamber, comprising:
a pair of paddles configured to support and transfer the boat; and
a heater which is adjacent to the pair of paddles and heats the boat on a bottom surface of the boat,
wherein the boat is inserted into the process chamber after the heater heats the boat to a predetermined temperature.

2. The boat loading device of claim 1, wherein the pair of paddles are spaced apart from each other on the bottom surface of the boat, and
the heater is positioned between the pair of paddles and overlaps a center of the boat in a width direction.

3. The boat loading device of claim 1, wherein the heater is positioned at least along an entire longitudinal direction of the plurality of wafers, which are stacked in the boat.

4. The boat loading device of claim 1, further comprising a shielding plate positioned between the pair of paddles and configured to surround the heater.

5. The boat loading device of claim 4, wherein the heater includes a lamp configured to radiate light, and
an inner surface of the shield plate facing the heater is made of a material capable of reflecting the light.

6. The boat loading device of claim 4, wherein the shielding plate has two ends in a width direction adjacent to the pair of paddles and is formed to be inclined such that a cross-sectional area thereof gradually decreases downward.

7. A wafer processing system comprising:
a process chamber configured to heat boats each stacked with a plurality of wafers in a predetermined atmosphere;
a boat stacking device configured to stack the plurality of boats;
a boat transfer device configured to transfer the boats; and
a boat loading device configured to load the boats transferred from the boat transfer device and insert the boats into the process chamber,
wherein at least one of the boat stacking device, the boat transfer device, and the boat loading device preheats the boat before the boat is inserted into the process chamber.

8. The wafer processing system of claim 7, wherein the at least one of the boat stacking device, the boat transfer device, and the boat loading device includes a heater which overlaps a center of the boat on a bottom surface of the boat and heats the boat.

9. The wafer processing system of claim 8, wherein the at least one of the boat stacking device, the boat transfer device, and the boat loading device further includes a shielding plate configured to surround the heater.
